(19) United States
(12) Patent Application Publication
(10) Pub. No.: US 2025/0197577 A1
(43) Pub. Date: Jun. 19, 2025

(54) LAYERED BODY, METHOD FOR MANUFACTURING SAME, AND METHOD FOR MANUFACTURING SEMICONDUCTOR PACKAGE

(71) Applicant: AGC Inc., Tokyo (JP)

(72) Inventors: Seigo KOTERA, Tokyo (JP); Satoshi TAKENAKA, Tokyo (JP); Junetsu NAKAMURA, Tokyo (JP)

(73) Assignee: AGC Inc., Tokyo (JP)

(21) Appl. No.: 19/062,367

(22) Filed: Feb. 25, 2025

Related U.S. Application Data
(63) Continuation of application No. PCT/JP2023/031100, filed on Aug. 29, 2023.

(30) Foreign Application Priority Data
Sep. 1, 2022 (JP) 2022-139312

(51) Int. Cl. C08J 7/04; C08J 3/28; H01L 21/56; H01L 23/29

(52) U.S. Cl. CPC C08J 7/042; C08J 3/28; H01L 21/565; H01L 23/295; C08J 2327/18

(57) ABSTRACT

This layered body is a layered body including a film-like base material and an antistatic layer provided on one surface of the base material, wherein a surface of the base material that is contact with the antistatic layer has a surface energy of 35 to 70 mN/m, and a thickness deviation of the antistatic layer is less than 30%.

The present application is a continuation application of International application No. PCT/JP2023/031100, filed on Aug. 29, 2023, which claims the priority of Japanese Patent Application No. 2022-139312, filed Sep. 1, 2022, the content of which is incorporated herein by reference.

### BACKGROUND OF THE INVENTION

### Field of Invention

The present disclosure relates to a layered body, a method for producing the same, and a method for producing a semiconductor package.

### Description of Related Art

Fluororesin films have excellent mold releasability and the like and are used as process films for forming electronic components such as semiconductor encapsulation. On the other hand, fluororesin films are easily charged with static electricity, and care must be taken for operations such as contact with and separation from electronic circuits. When using a fluororesin film, not only for a semiconductor, but also during an encapsulation step for SiP (System-in-Package), three-dimensional packaging, and the like, there is a concern that electronic circuits to be encapsulated may be damaged. Therefore, provision of a fluorine film with an antistatic function is extremely beneficial from an industrial perspective.

As a fluorine film having an antistatic function, a film having an antistatic layer on one side of a fluororesin base material is known (Patent Documents 1 and 2).

### CITATION LIST

### Patent Documents

Patent Document 1: International Patent Publication No. 2016/093178
Patent Document 2: International Patent Publication No. 2016/125796

### SUMMARY OF INVENTION

Incidentally, the antistatic function required during an encapsulation step for the above-mentioned three-dimensional packaging and the like may require uniformity.

According to intensive and extensive studies by the inventors of the present invention, the antistatic function of the fluorine film having an antistatic function described in Patent Documents 1 and 2 may not be uniform.

The present disclosure provides a layered body exhibiting excellent antistatic performance, a method for producing the same, and a method for producing a semiconductor package using this layered body.

### Solution to Problem

The present disclosure provides a layered body having the following configurations [1] to [14], a method for producing the same, and a method for producing a semiconductor package.

[1]A layered body including a film-like base material and an antistatic layer provided on one surface of the aforementioned base material,
wherein a surface of the aforementioned base material that is contact with the aforementioned antistatic layer has a surface energy of 35 to 70 mN/m, and
a thickness deviation of the aforementioned antistatic layer is less than 30%.

[2] The layered body according to [1] above, wherein the aforementioned antistatic layer contains a water-dispersible antistatic agent.

[3] The layered body according to [2] above, wherein the aforementioned antistatic agent contains at least one selected from the group consisting of a conductive polymer and a conductive filler.

[4] The layered body according to any one of [1] to [3] above, wherein the aforementioned base material contains at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

[5] The layered body according to [4] above, wherein the aforementioned fluororesin contains at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

[6] The layered body according to any one of [1] to [5] above, wherein a surface of the aforementioned base material that is contact with the aforementioned antistatic layer is subjected to a corona treatment or plasma treatment.

[7] The layered body according to any one of [1] to [6] above, further including a release layer provided on a surface of the aforementioned antistatic layer opposite to the aforementioned base material.

[8] The layered body according to any one of [1] to [7] above, which is a mold release film used in a step of encapsulating a semiconductor element with a curable resin.

[9]A production method of a layered body including applying a coating liquid for antistatic layers onto one surface of a film-like base material to form an antistatic layer,
wherein a surface of the aforementioned base material onto which the aforementioned coating liquid for antistatic layers is applied has a surface energy of 35 to 70 mN/m,
the aforementioned coating liquid for antistatic layers contains water, a water-miscible organic solvent, and a water-dispersible antistatic agent,
a content of the aforementioned water is from 50.0 to 99.9% by mass with respect to a total amount of the aforementioned coating liquid for antistatic layers,
a content of the aforementioned water-miscible organic solvent is from 14.0 to 30.0% by mass with respect to the total amount of the aforementioned coating liquid for antistatic layers, and
a surface tension of the aforementioned coating liquid for antistatic layers is 34 mN/m or less.

[10] The production method according to [9] above, wherein the aforementioned water-miscible organic solvent contains an alcohol.

[11] The production method according to [10] above, wherein the aforementioned alcohol contains isopropyl alcohol.

[12] The production method according to any one of [9] to [11] above, wherein a surface of the aforementioned base material onto which the aforementioned coating liquid for antistatic layers is to be applied is subjected to a corona treatment or a plasma treatment before applying the aforementioned coating liquid for antistatic layers.

[13] The production method according to any one of [9] to [12] above, further including forming a release layer on a surface of the aforementioned antistatic layer opposite the aforementioned base material after forming the aforementioned antistatic layer.

[14]A method for producing a semiconductor package, the method including:
placing the layered body according to any one of [1] to [8] above on an inner surface of a mold;
placing a substrate to which a semiconductor element is fixed in the aforementioned mold on which the aforementioned layered body is placed;
encapsulating the semiconductor element in the aforementioned mold with a curable resin to produce an encapsulated body; and releasing the aforementioned encapsulated body from the aforementioned mold.

### Advantageous Effects of Invention

According to the present disclosure, it is possible to provide a layered body exhibiting excellent antistatic performance, a method for producing the same, and a method for producing a semiconductor package using this layered body.

### BRIEF DESCRIPTION OF DRAWINGS

FIG. 1 A schematic cross-sectional view showing one embodiment of the present layered body.

FIG. 2 A schematic cross-sectional view showing another embodiment of the present layered body.

### DETAILED DESCRIPTION OF THE INVENTION

Hereinafter, embodiments of the present disclosure will be described in detail. However, the embodiments of the present disclosure are not limited to the following embodiments. In the following embodiments, the constituent elements thereof (including element steps and the like) are not essential unless otherwise specified. The same applies to numerical values and ranges thereof, which do not limit the embodiments of the present disclosure.

In the present disclosure, the term “step” includes not only a step that is independent of other steps, but also a step that cannot be clearly distinguished from other steps, as long as the purpose of this step is achieved.

In the present disclosure, a numerical value range indicated by using “to” includes numerical values described before and after “to” as a minimum value and a maximum value, respectively.

In a numerical value range described in stages in the present disclosure, an upper limit value or a lower limit value described in one numerical value range may be replaced with an upper limit value or a lower limit value of another numerical value range described in stages. Further, in a numerical value range described in the present disclosure, an upper limit value or a lower limit value of the numerical value range may be replaced with a value shown in Examples.

In the present disclosure, each component may contain a plurality of types of corresponding substances. When a plurality of types of substances corresponding to each component are present in a composition, a content ratio or content of each component means a total content ratio or content of the plurality of types of substances present in the composition unless otherwise specified.

When an embodiment is described in the present disclosure with reference to a drawing, configurations of this embodiment are not limited to configurations shown in the drawing. Further, the sizes of members in the drawing are conceptual, and a relative relationship between the sizes of the members is not limited thereto.

In the present disclosure, a “unit” of a polymer means a portion derived from a monomer that exists in the polymer and constitutes the polymer. In addition, one obtained by chemically converting a structure of a certain unit after polymer formation is also referred to as a unit. It should be noted that in some cases, a unit derived from an individual monomer is referred to by a name obtained by adding a “unit” to a name of the monomer.

In the present disclosure, a film and a sheet are referred to as a “film” regardless of a thickness thereof.

In the present disclosure, acrylate and methacrylate are collectively referred to as “(meth)acrylate”, acrylic and methacrylic are collectively referred to as “(meth)acrylic”, and (meth)acryloyl and methacryloyl are collectively referred to as “(meth)acryloyl”.

In the present disclosure, a (meth)acrylic polymer is a polymer having a monomer with a (meth)acryloyl group or a unit based on (meth)acrylic acid. Hereinafter, a monomer with a (meth)acryloyl group or (meth)acrylic acid is also referred to as a “(meth)acrylic monomer”.

### [Layered Body]

A layered body according to one embodiment of the present disclosure (hereinafter also referred to as a “layered body”) is a layered body including a film-like base material and an antistatic layer provided on one surface of the aforementioned base material, wherein a surface of the aforementioned base material that is contact with the aforementioned antistatic layer has a surface energy of 35 to 70 mN/m, and a thickness deviation of the aforementioned antistatic layer is less than 30%.

The present layered body has been found to exhibit excellent antistatic performance.

According to intensive and extensive studies by the inventors of the present invention, the antistatic layer of the present layered body has a higher conductivity per antistatic layer thickness and is excellent in conductivity, compared to cases in which the deviation in thickness of the antistatic layer is 30% or more. The surface resistance value of the layered body can be reduced because of excellent conductivity of the antistatic layer, which results in excellent antistatic performance. The reason for the high conductivity per thickness of the antistatic layer is thought to be that the antistatic layer is formed with a uniform thickness, which results in uniform distribution and orientation of the antistatic agent and formation of a uniform conductive path.

In addition, when the deviation in thickness of the antistatic layer is less than 30%, color unevenness caused by thickness unevenness of the antistatic layer is suppressed, resulting in excellent appearance.

The present layered body only needs to include a base material and an antistatic layer, and other configurations are not particularly limited.

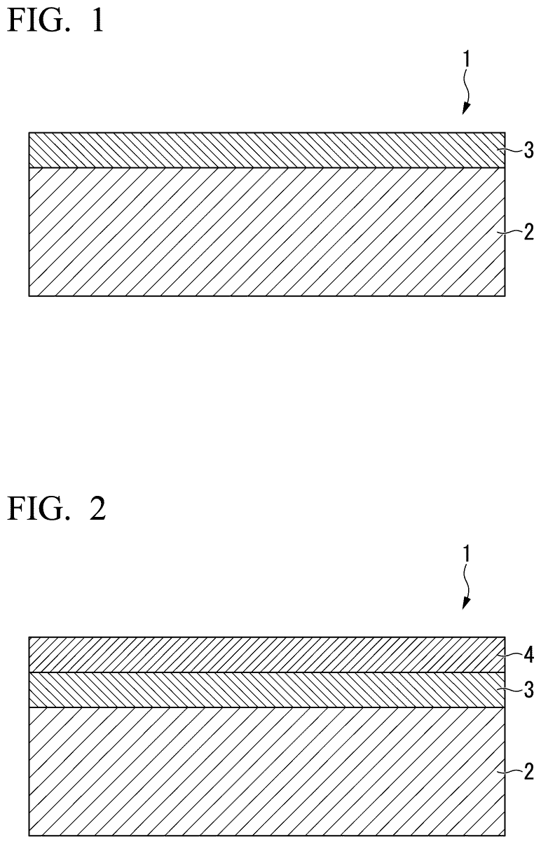

FIG. 1 is a schematic cross-sectional view showing one embodiment of the present layered body. A layered body 1 shown in FIG. 1 includes a base material 2 and an antistatic layer 3 in this order. FIG. 2 is a schematic cross-sectional view showing another embodiment of the present layered body. A layered body 1 shown in FIG. 2 includes a base material 2, an antistatic layer 3, and a release layer 4 in this order. When the layered body 1 is used to encapsulate a semiconductor element, the base material 2 is placed so as to be in contact with a mold, and after resin encapsulation, the antistatic layer 3 or the release layer 4 is brought into contact with an encapsulated body (that is, a semiconductor package in which the semiconductor element is encapsulated). The layered body 1 may include other layers in addition to the base material 2, the antistatic layer 3, and the release layer 4.

Hereinafter, each constituent element of the present layered body will be described in detail.

### (Base Material)

A material of the base material is not particularly limited.

The base material typically contains a resin. Examples of the resin include a fluororesin, polymethylpentene, syndiotactic polystyrene, a polycycloolefin, a silicone rubber, a polyester elastomer, polybutylene terephthalate, polyethylene terephthalate, and a polyamide.

In one aspect, from the viewpoint of excellent mold releasability of the present layered body, the base material preferably contains a resin having mold releasability (hereinafter also referred to as a “releasable resin”). The term “releasable resin” means a resin in which a layer composed of this resin has mold releasability. Examples of the releasable resin include a fluororesin, polymethylpentene, syndiotactic polystyrene, a polycycloolefin, a silicone rubber, a polyester elastomer, polybutylene terephthalate, and a polyamide. From the viewpoint of excellent mold releasability, heat resistance, strength, and elongation at a high temperature, a fluororesin, polymethylpentene, syndiotactic polystyrene, and a polycycloolefin are preferred, and from the viewpoint of excellent mold releasability, a fluororesin is more preferred.

One type or two or more types of resins may be contained in the base material. It is particularly preferable that the base material is composed of a fluororesin alone. However, even when the base material is composed of a fluororesin alone, this does not prevent the inclusion of resins other than the fluororesin within a range that does not impair the effects of the invention.

The fluororesin is preferably a fluoroolefin polymer from the viewpoint of excellent mold releasability and heat resistance. The fluoroolefin polymer is a polymer having a unit based on a fluoroolefin. The fluoroolefin polymer may further have a unit other than the unit based on a fluoroolefin.

Examples of the fluoroolefin include tetrafluoroethylene (hereinafter also referred to as “TFE”), vinyl fluoride, vinylidene fluoride, trifluoroethylene, hexafluoropropylene (hereinafter also referred to as “HFP”), and chlorotrifluoroethylene. One type of fluoroolefin may be used alone, or two or more types thereof may be used in combination.

Examples of the fluoroolefin polymer include an ethylene-TFE copolymer (hereinafter also referred to as “ETFE”), a TFE-HFP copolymer (hereinafter also referred to as “FEP”), a TFE-perfluoro(alkyl vinyl ether) copolymer, and a TFE-HFP-vinylidene fluoride copolymer. From the viewpoint of mechanical properties, at least one selected from the group consisting of ETFE and FEP is preferred. One type of fluoroolefin polymer may be used alone, or two or more types thereof may be used in combination.

From the viewpoint of large elongation at a high temperature, ETFE is preferred as the fluoroolefin polymer. ETFE is a copolymer having a unit based on TFE (hereinafter, also referred to as a “TFE unit”) and a unit based on ethylene (hereinafter, also referred to as an “E unit”).

The ETFE is preferably a polymer having a TFE unit, an E unit, and a unit based on a third monomer other than TFE and ethylene. Depending on the type and content of the unit based on the third monomer, the degree of crystallinity of the ETFE can be easily adjusted, and thus a storage elastic modulus or other tensile properties of the base material can be easily adjusted. For example, when the ETFE has the unit based on a third monomer (particularly, a monomer having a fluorine atom), a tensile strength and elongation at a high temperature (particularly, around 180° C.) tends to be improved.

Examples of the third monomer include a monomer having a fluorine atom and a monomer having no fluorine atoms.

Examples of the monomer having a fluorine atom include the following monomers a1 to a5.

Monomer a1: fluoroolefins having 2 or 3 carbon atoms.

Monomer a2: fluoroalkylethylenes represented by X(CF₂)nCY=CH₂ (where X and Y each independently represent a hydrogen atom or a fluorine atom, and n is an integer of 2 to 8).

Monomer a3: fluorovinyl ethers.

Monomer a4: functional group-containing fluorovinyl ethers.

Monomer a5: a fluorine-containing monomer having an aliphatic ring structure.

Specific examples of the monomer a1 include fluoroethylenes (for example, trifluoroethylene, vinylidene fluoride, vinyl fluoride, chlorotrifluoroethylene, and the like) and fluoropropylenes (hexafluoropropylene (HFP), 2-hydropentafluoropropylene, and the like).

As the monomer a2, a monomer in which n is 2 to 6 is preferred, and a monomer in which n is 2 to 4 is more preferred. Further, a monomer in which X is a fluorine atom and Y is a hydrogen atom, that is, (perfluoroalkyl)ethylene is preferred.

Specific examples of the monomer a2 include the following compounds.
CF₃CF₂CH═CH₂,
CF₃CF₂CF₂CF₂CH═CH₂ ((perfluorobutyl)ethylene (hereinafter also referred to as “PFBE”)),
CF₃CF₂CF₂CF₂CF═CH₂,
CF₂HCF₂CF₂CF═CH₂,
CF₂HCF₂CF₂CF₂CF═CH₂.

Specific examples of the monomer a3 include the following compounds. It should be noted that among the following, a monomer that is a diene is a monomer capable of undergoing cyclopolymerization.
CF₂═CFOCF₃,
CF₂═CFOCF₂CF₃,
CF₂═CFO(CF₂)₂CF₃ (perfluoro(propyl vinyl ether) (hereinafter also referred to as “PPVE”)),
CF₂═CFOCF₂CF(CF₃)O(CF₂)₂CF₃,
CF₂═CFO(CF₂)₃O(CF₂)₂CF₃,
CF₂═CFO(CF₂CF(CF₃)O)₂(CF₂)₂CF₃,
CF₂═CFOCF₂CF(CF₃)O(CF₂)₂CF₃,
CF₂═CFOCF₂CF═CF₂,
CF₂═CFO(CF₂)₂CF═CF₂.

Specific examples of the monomer a4 include the following compounds.
CF₂═CFO(CF₂)₃CO₂CH₃,
CF₂═CFOCF₂CF(CF₃)O(CF₂)₃CO₂CH₃,
CF₂═CFOCF₂CF(CF₃)O(CF₂)₂SO₂F.

Specific examples of the monomer a5 include perfluoro(2,2-dimethyl-1,3-dioxole), 2,2,4-trifluoro-5-trifluoromethoxy-1,3-dioxole, and perfluoro(2-methylene-4-methyl-1,3-dioxolane).

Examples of the monomer having no fluorine atoms include the following monomers b1 to b4.

Monomer b1: olefins.

Monomer b2: vinyl esters.

Monomer b3: vinyl ethers.

Monomer b4: an unsaturated acid anhydride.

Specific examples of the monomer b1 include propylene and isobutene.

Specific examples of the monomer b2 include vinyl acetate.

Specific examples of the monomer b3 include ethyl vinyl ether, butyl vinyl ether, cyclohexyl vinyl ether, and hydroxybutyl vinyl ether.

Specific examples of the monomer b4 include maleic anhydride, itaconic anhydride, citraconic anhydride, and 5-norbornene-2,3-dicarboxylic anhydride.

One type of the third monomer may be used alone, or two or more types thereof may be used in combination.

As the third monomer, from the viewpoint of easy adjustment of the degree of crystallinity and from the viewpoint of excellent tensile strength at a high temperature (particularly around 180° C.), the monomer a2, HFP, PPVE, and vinyl acetate are preferred, HFP, PPVE, CF₃CF₂CH═CH₂, and PFBE are more preferred, and PFBE is particularly preferred. That is, as the ETFE, a copolymer having a TFE unit, an E unit, and a unit based on PFBE (hereinafter, also referred to as a “PFBE unit”) is particularly preferred.

In the ETFE, a molar ratio of the TFE unit with respect to the E unit (TFE unit/E unit) is preferably from 80/20 to 40/60, more preferably from 70/30 to 45/55, and still more preferably from 65/35 to 50/50. When the TFE unit/E unit ratio is within the above range, the ETFE exhibits excellent heat resistance and mechanical strength.

A ratio of the unit based on the third monomer in the ETFE is preferably from 0.01 to 20 mol %, more preferably from 0.10 to 15 mol %, and still more preferably from 0.20 to 10 mol %, with respect to the total (100 mol %) of all units constituting the ETFE. When the ratio of the unit based on the third monomer is within the above range, the ETFE exhibits excellent heat resistance and mechanical strength.

When the unit based on the third monomer includes a PFBE unit, a ratio of the PFBE unit is preferably from 0.5 to 4.0 mol %, more preferably from 0.7 to 3.6 mol %, and still more preferably from 1.0 to 3.6 mol %, with respect to the total (100 mol %) of all units constituting the ETFE. When the ratio of the PFBE unit is within the above range, the tensile strength of the present layered body at a high temperature, particularly at around 180° C., is improved.

The base material may be composed only of the resin, or may further contain other components in addition to the resin. Examples of the other components include a lubricant, an antioxidant, an antistatic agent, a plasticizer, and a mold release agent. From the viewpoint of preventing staining of the mold, it is preferable that the base material does not contain other components.

A thickness of the base material is preferably from 6 to 500 μm, more preferably from 25 to 300 μm, and still more preferably from 25 to 150 μm. When the thickness of the base material is equal to or less than the upper limit value of the above range, the present layered body can be easily deformed and exhibits excellent mold followability. When the thickness of the base material is equal to or more than the lower limit value of the above range, handling of the present layered body, for example, roll-to-roll handling, is easy, and wrinkles are less likely to occur when the present layered body is placed so as to cover a mold cavity while being stretched.

The thickness of the base material can be measured in accordance with an ISO 4591:1992 (JIS K7130:1999) B1 method: a method for measuring the thickness of a sample taken from a plastic film or sheet by a weighing method).

The surface of the base material may have a surface roughness. An arithmetic average roughness Ra of the surface of the base material is preferably from 0.2 to 3.0 μm, and more preferably from 0.5 to 2.5 μm. When the arithmetic average roughness Ra of the surface of the base material is equal to or more than the lower limit value of the above range, the releasability from the mold is further improved. When the arithmetic average roughness Ra of the surface of the base material is equal to or less than the upper limit value of the above range, pinholes are less likely to be formed in the present layered body.

The arithmetic average roughness Ra is measured based on JIS B0601:2013 (ISO 4287:1997, Amd.1:2009). A reference length lr (cutoff value λc) for a roughness curve is 0.8 mm.

The base material may be unstretched or stretched. For example, unstretched polyamide films, biaxially stretched polyamide films, biaxially stretched PET (polyethylene terephthalate) films, biaxially stretched PEN (polyethylene naphthalate) films, biaxially stretched syndiotactic polystyrene films, and unstretched PBT (polybutylene terephthalate) films are commercially available. In addition, polyimide films, polyphenylene sulfide resin films, cross-linked polyethylene films, and the like can be used.

The surface of the base material may be subjected to any surface treatment. Examples of the surface treatment include a corona treatment, a plasma treatment, a frame treatment, a UV-ozone treatment, coating with a silane coupling agent, and coating with an adhesive.

The surface of the base material that is contact with the antistatic layer is preferably subjected to a hydrophilization treatment from the viewpoint of setting the surface energy thereof to 35 mN/m or more. The hydrophilization treatment may be any treatment that reduces the surface energy of the treated surface, and examples thereof include a corona treatment, a plasma treatment, a frame treatment, and a UV-ozone treatment. Among these, a corona treatment or a plasma treatment is preferred from the viewpoints of the simplicity of the equipment and ease of introduction into industrial processes. When a corona treatment or a plasma treatment is performed, a hydrophilic functional group is generated on the surface, and the surface energy is reduced.

The base material may be a single layer or may have a multilayer structure. Examples of the multilayer structure include a structure in which a plurality of layers each containing a resin are laminated. In this case, the resins contained in each of the plurality of layers may be the same as or different from each other. From the viewpoints of mold followability, tensile elongation, production costs, and the like, the base material is preferably a single layer. From the viewpoint of the strength of the layered body, the base material preferably has a multilayer structure.

The multilayer structure may be, for example, a structure in which a structure in which a layer containing the above-mentioned releasable resin (preferably a fluororesin) is laminated on a resin film containing a resin (which may be a film containing only a resin) such as polyester or polybutylene terephthalate, polystyrene (preferably syndiotactic), or polycarbonate; or a structure in which a layer containing a first release resin, the above resin film, and a layer containing a second release resin are laminated in this order. The layer containing the releasable resin and the resin film may be laminated via an adhesive. One surface or both surfaces of each layer containing the releasable resin may be subjected to a corona treatment or a plasma treatment. When the base material has such a multilayer structure, it is preferable that the layer containing the releasable resin is disposed on the antistatic layer side. When the base material has such a multilayer structure, it is preferable that the surface on the antistatic layer side of the layer containing the releasable resin and disposed on the antistatic layer side is subjected to a corona treatment or a plasma treatment.

The surface energy of the surface of the base material that is contact with the antistatic layer is preferably from 35 to 70 mN/m, more preferably from 35 to 65 mN/m, and still more preferably from 40 to 60 mN/m. When the surface energy of the surface of the base material that is contact with the antistatic layer is equal to or more than the above lower limit value, the coating liquid for antistatic layers described below can be uniformly applied, and the deviation in thickness of the antistatic layer can be reduced. When the surface energy of the surface of the base material that is contact with the antistatic layer is equal to or less than the above upper limit value, this surface energy can be easily adjusted by a corona treatment or a plasma treatment.

The surface energy of the surface of the base material that is contact with the antistatic layer can be adjusted by the material of the base material constituting this surface, a surface treatment, and the like.

The surface energy of the surface of the base material that is contact with the antistatic layer is preferably 20 mN/m or more, more preferably 30 mN/m or more, and particularly preferably 35 mN/m or more, from the viewpoint of adhesion between the base material and the antistatic layer. An upper limit of the surface energy is not particularly limited, and may be 80 mN/m or less.

The surface energy is determined by a surface energy evaluation method using a wetting indicator based on IS08296:2003.

More specifically, the surface energy is determined by the following method.

A test piece is placed on a horizontal table and a liquid mixture for a test (test mixture) is spread using a cotton swab. The test mixture is quickly spread over an area of at least 6 cm². The amount of the test mixture is set to a degree such that a thin layer is formed without creating any puddles. The surface energy is determined by observing a liquid film of the test mixture in a bright place and observing the state of the liquid film after 2 seconds. A case in which the liquid film does not break and the state at the time of application is maintained is judged to be wet. The method further proceeds to a step of determining the surface energy of a liquid mixture with a high surface tension if it is judged to be wet, and proceeds to a step of determining the surface energy of a liquid mixture with a low surface tension if it is judged not to be wet. This operation is repeated to select a liquid mixture that can wet the surface of the test piece accurately in 2 seconds. The operation of selecting a liquid mixture that can wet the surface of the test piece in 2 seconds is performed at least three times. The surface tension of the liquid mixture selected in this manner is taken as the surface energy of the film.

### (Antistatic Layer)

The antistatic layer is not particularly limited as long as it is a layer that has an antistatic function. The antistatic layer is provided on the base material so as to be adjacent to the base material. The surface of the base material may be modified by some kind of treatment. In that case, the modified surface is regarded as the surface characteristics of the base material and can be regarded as the “base material” of the present invention.

The antistatic layer may contain an antistatic agent. Examples of the antistatic agent include an ionic liquid, a conductive polymer, and a conductive filler. One type of the antistatic agent may be used alone, or two or more types thereof may be used in combination.

Examples of the ionic liquid include oniums such as pyridinium and imidazolium, and fluorine-based compounds.

The conductive polymer is a polymer in which electrons move and diffuse along a skeleton of the polymer. Examples of the conductive polymer include a polyaniline-based polymer, a polyacetylene-based polymer, a polyparaphenylene-based polymer, a polypyrrole-based polymer, a polythiophene-based polymer, and a polyvinylcarbazole-based polymer.

Examples of the conductive filler include a metal ion conductive salt, a metal-based filler, a metal oxide-based filler, a metal-coated filler, a metal oxide-coated filler, a conductive carbon filler, and a conductive carbon nanotube filler.

Examples of the metal ion conductive salt include a lithium salt compound.

Examples of the metal oxide in the metal oxide-based filler and metal oxide-coated filler include tin oxide, tin-doped indium oxide, antimony-doped tin oxide, phosphorus-doped tin oxide, zinc antimonate, and antimony oxide.

The antistatic agent is preferably one having excellent electrical conductivity, and more preferably at least one selected from the group consisting of a conductive polymer and a conductive filler. A conductive polymer or a conductive filler is generally highly hydrophilic and is used as a dispersion coating liquid mainly composed of water.

The antistatic agent is preferably dispersed in a binder resin. In other words, the antistatic layer is preferably a layer in which an antistatic agent is dispersed in a binder resin.

The binder resin preferably has heat resistance. For example, when the present layered body is used in a step for encapsulating a semiconductor element, it is preferable that the binder resin has heat resistance at about 180° C.

From the viewpoint of excellent heat resistance, the binder resin preferably contains at least one selected from the group consisting of an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Among these, from the viewpoint of excellent mechanical strength, it is preferable to be composed of at least one (for example, only an acrylic resin) selected from the group consisting of an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Furthermore, from the viewpoint of excellent heat resistance and dispersibility of the antistatic agent, at least one selected from the group consisting of a polyester resin and an acrylic resin is preferred.

In the antistatic layer, the binder resin may be crosslinked. When the binder resin is crosslinked, the strength and heat resistance are superior as compared with a case where it is not crosslinked.

In one aspect, from the viewpoint of coating film strength and durability, the antistatic layer preferably contains, as the binder resin, a reaction cured product of a carboxy group-containing (meth)acrylic polymer and at least one selected from the group consisting of a bifunctional or higher aziridine compound (hereinafter also referred to as a “polyfunctional aziridine compound”) and a bifunctional or higher epoxy compound (hereinafter also referred to as a “polyfunctional epoxy compound”). In this case, the carboxy group-containing (meth)acrylic polymer reacts and crosslinks with at least one selected from the group consisting of a polyfunctional aziridine compound and a polyfunctional epoxy compound to form a reaction cured product. The antistatic layer may be a reaction cured product of the carboxy group-containing (meth)acrylic polymer, at least one selected from the group consisting of a polyfunctional aziridine compound and a polyfunctional epoxy compound, and other components.

A ratio of the unit based on the (meth)acrylic monomer with respect to the entire (meth)acrylic polymer is not particularly limited, and is preferably 50% by mass or more, more preferably 60% by mass or more, still more preferably 70% by mass or more, and particularly preferably 80% by mass or more.

A carboxy group included in the carboxy group-containing (meth)acrylic polymer is a crosslinkable functional group that reacts with an aziridine group in the polyfunctional aziridine compound or an epoxy group in the polyfunctional epoxy compound.

An acid value of the carboxy group-containing (meth)acrylic polymer is preferably from 1 to 80 mgKOH/g, more preferably from 1 to 40 mgKOH/g, still more preferably from 1 to 30 mgKOH/g, and particularly preferably from 5 to 30 mgKOH/g. The acid value of the carboxy group-containing (meth)acrylic polymer is an index of the ease of forming crosslinks when reacting with the polyfunctional aziridine compound or the polyfunctional epoxy compound. When the acid value is equal to or less than the above upper limit value, the antistatic layer exhibits excellent extensibility. When the acid value is equal to or more than the above lower limit value, the antistatic layer exhibits excellent adhesion.

When a plurality of types of (meth)acrylic polymers are used in the antistatic layer, the above range is a preferred range for the acid value of this plurality of types of (meth)acrylic polymers as a whole.

The acid value of the (meth)acrylic polymer is measured by a method specified in JIS K0070:1992.

In the carboxy group-containing (meth)acrylic polymer, the carboxy group may be present in a side group, may be present at the end of the main chain, or may be present in both the side chain and the main chain. From the viewpoint of ease of adjusting the content of the carboxy group, it is preferably present at least in a side group.

Examples of the carboxy group-containing (meth)acrylic polymer in which a carboxy group is present in a side group include a (meth)acrylic polymer having a unit based on a carboxy group-containing monomer.

Examples of the carboxy group-containing monomer include a carboxy group-containing (meth)acrylic monomer. Examples of the carboxy group-containing (meth)acrylic monomer include a carboxy group-containing (meth)acrylate and (meth)acrylic acid. Examples of the carboxy group-containing (meth)acrylate include ω-carboxy-polycaprolactone mono(meth)acrylate and mono-2-((meth)acryloyloxy)ethylsuccinic acid. One type of these monomers may be used alone or two or more types thereof may be used in combination.

The carboxy group-containing (meth)acrylic polymer may be composed only of a unit based on a carboxy group-containing monomer, or may further have a unit based on a monomer other than the carboxy group-containing monomer.

Examples of the monomer other than the carboxy group-containing monomer include a (meth)acrylate that does not contain a hydroxyl group and a carboxy group, and a hydroxyl group-containing (meth)acrylate. One type of these monomers may be used alone or two or more types thereof may be used in combination.

Examples of the (meth)acrylate that does not contain a hydroxyl group and a carboxy group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl)trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound whose alkyl group has 1 to 12 carbon atoms, and examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

Examples of the hydroxyl group-containing (meth)acrylate include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid.

A mass average molecular weight (hereinafter also referred to as “Mw”) of the carboxy group-containing (meth)acrylic polymer is preferably from 10,000 to 1,000,000, more preferably from 50,000 to 800,000, and still more preferably from 100,000 to 600,000. When Mw is equal to or more than the above lower limit value, the antistatic layer exhibits excellent strength. When Mw is equal to or less than the above upper limit value, the antistatic layer exhibits excellent extensibility.

The Mw of the carboxy group-containing (meth)acrylic polymer is a polystyrene-equivalent value obtained by measurement by gel permeation chromatography using a calibration curve produced using a standard polystyrene sample having a known molecular weight.

A polyfunctional aziridine compound is a compound having two or more aziridine groups in one molecule. The number of aziridine groups in a polyfunctional aziridine compound is preferably 6 or less, and particularly preferably 3 or less, from the viewpoint of obtaining high extensibility without excessively increasing the crosslinking density of the antistatic layer.

Examples of the polyfunctional aziridine compound include 2,2-bishydroxymethylbutanol-tris[3-(1-aziridinyl)propionate], 4,4-bis(ethyleneiminocarbonylamino)diphenylmethane, and trimethylolpropane-tris(p-aziridinyl)propionate. One type of the polyfunctional aziridine compound may be used alone or two or more types thereof may be used in combination.

A commercially available product may be used as the polyfunctional aziridine compound. Examples of the commercially available product include Aracoat CL910 (product name) manufactured by Arakawa Chemical Industries, Ltd., Chemitite (registered trademark) DZ-22E (product name) manufactured by Nippon Shokubai Co., Ltd., and Chemitite (registered trademark) PZ-33 (product name) manufactured by Nippon Shokubai Co., Ltd.

The aziridine equivalent of the polyfunctional aziridine compound is preferably 50 g/eq or more, more preferably 75 g/eq or more, and still more preferably 100 g/eq or more, from the viewpoint of obtaining high extensibility without excessively increasing the crosslinking density of the antistatic layer. From the viewpoint of increasing the strength of the antistatic layer, the aziridine equivalent of the polyfunctional aziridine compound is preferably 300 g/eq or less, and more preferably 250 g/eq or less. From such viewpoints, the aziridine equivalent of the polyfunctional aziridine compound is preferably from 75 to 250 g/eq, and more preferably from 100 to 200 g/eq.

A polyfunctional epoxy compound is a compound having two or more epoxy groups in one molecule. The number of epoxy groups in the polyfunctional epoxy compound is preferably 6 or less, and particularly preferably 3 or less, from the viewpoint of obtaining high extensibility without excessively increasing the crosslinking density of the antistatic layer.

Examples of the polyfunctional epoxy compound include N,N,N′,N′-tetraglycidyl-m-xylylenediamine, 1,3-bis(N,N-diglycidylaminomethyl)cyclohexane, resorcinol diglycidyl ether, and glycerol polyglycidyl ether. One type of the epoxy compound may be used alone or two or more types thereof may be used in combination.

A commercially available product may be used as the polyfunctional epoxy compound. Examples of the commercially available product include TETRAD-X (product name) and TETRAD-C(product name) manufactured by Mitsubishi Gas Chemical Company, Inc., and Denacol (registered trademark) EX-201 (product name) and Denacol (registered trademark) EX-313 (product name) manufactured by Nagase ChemteX Corporation.

The epoxy equivalent of the polyfunctional epoxy compound is preferably 30 g/eq or more, more preferably 50 g/eq or more, and still more preferably 90 g/eq or more, from the viewpoint of obtaining high extensibility without excessively increasing the crosslinking density of the antistatic layer. From the viewpoint of increasing the strength of the antistatic layer, the epoxy equivalent of the polyfunctional epoxy compound is preferably 300 g/eq or less, more preferably 200 g/eq or less, still more preferably 150 g/eq or less, and particularly preferably 120 g/eq or less. From such viewpoints, the epoxy equivalent of the polyfunctional epoxy compound is preferably from 30 to 300 g/eq, more preferably from 50 to 200 g/eq, and still more preferably from 90 to 120 g/eq.

The total ratio of the aziridine groups of the polyfunctional aziridine compound and the epoxy groups of the polyfunctional epoxy compound with respect to 100 mol % of the carboxy groups of the carboxy group-containing (meth)acrylic polymer is preferably from 15 to 130 mol %, and particularly preferably from 25 to 60 mol %. When the total ratio of the aziridine groups and the epoxy groups is equal to or less than the above upper limit value, the crosslinking density is sufficiently low, and the antistatic layer exhibits excellent extensibility. In addition, when a release layer is provided on the antistatic layer, the adhesion between the release layer and the antistatic layer is excellent. When the total ratio of the aziridine groups and the epoxy groups is equal to or more than the above lower limit value, the crosslinking density is sufficiently high, and the antistatic layer exhibits excellent strength.

The antistatic layer may contain other components other than the antistatic agent and the binder resin. Examples of the other components include a lubricant, a coloring agent, and a coupling agent.

Examples of the lubricant include microbeads made of a thermoplastic resin, fumed silica, and polytetrafluoroethylene (PTFE) fine particles.

Examples of the coloring agent include various organic coloring agents and inorganic coloring agents, and more specifically, examples thereof include cobalt blue, red iron oxide, and cyanine blue.

Examples of the coupling agent include a silane coupling agent and a titanate coupling agent.

From the viewpoint of sufficiently exhibiting the antistatic function, the content of the antistatic agent in the antistatic layer is preferably such an amount that the surface resistance value of the layered body is within a range to be described later.

In one aspect, when the antistatic layer is a layer in which the antistatic agent is dispersed in the binder resin, the content of the antistatic agent may be from 3 to 50% by mass or may be from 5 to 20% by mass with respect to the binder resin. When the content of the antistatic agent is equal to or more than the above lower limit value, the surface resistance value of the film is likely to be within a suitable range. When the content of the antistatic agent is equal to or less than the above upper limit value, the adhesion of the antistatic layer is likely to be favorable.

The total content of the antistatic agent and the binder resin in the antistatic layer is preferably 10% by mass or more, more preferably 50% by mass or more, still more preferably 60% by mass or more, and may be 100% by mass, with respect to the total mass of the antistatic layer.

The average thickness of the antistatic layer is, for example, from 100 to 20,000 nm, preferably from 100 to 2,000 nm, more preferably from 100 to 1,500 nm, and still more preferably from 100 to 1,000 nm. When the average thickness of the antistatic layer is equal to or more than the above lower limit value, the electrical conductivity is excellent. When the average thickness of the antistatic layer is equal to or less than the upper limit value of the above range, the stability of the production process including the appearance of the coated surface is excellent.

The average thickness of the antistatic layer is measured by optical interferometry. Details are as described in Examples below.

The deviation in thickness of the antistatic layer is less than 30%, preferably 20% or less, and more preferably 10% or less. The lower limit of the deviation in thickness of the antistatic layer is not particularly limited, and may be, for example, 0% or may be 0.1%. When the deviation in thickness of the antistatic layer is equal to or less than the above upper limit value, the conductivity per thickness of the antistatic layer is excellent. In addition, color unevenness caused by thickness unevenness of the antistatic layer is suppressed, and the appearance of the layered body is excellent.

The deviation in thickness of the antistatic layer may be measured using a general thickness measurement method. In particular, thicknesses of 2,000 nm or less are preferably measured by optical interferometry. More specifically, the deviation in thickness of the antistatic layer is determined by a method described in the section entitled <Thickness characteristics> in Examples to be described later. More specifically, the thickness of the antistatic layer is measured by optical interferometry at five points evenly spaced in the width direction of the layered body. The thickness of the antistatic layer is calculated using a reflection/transmission/film thickness measurement system (for example, F10-RT manufactured by Filmetrics, Inc.) with a refractive index of 1.49. The average value of thicknesses at the five points is taken as the average thickness of the antistatic layer. Further, the difference between the maximum value and the minimum value of thickness measured at the five points is taken as the “thickness variation at five points,” and the deviation in thickness of the antistatic layer is obtained using the following formula:

$$Deviation in thickness of antistatic layer ( \% ) = thickness variation at five points ( nm ) / average thickness ( nm ) \times 100$$

### (Release Layer)

The release layer may be provided on the antistatic layer while being adjacent to the antistatic layer, or may be provided on the antistatic layer via another layer adjacent to the antistatic layer.

A material of the release layer is not particularly limited.

The release layer may be a layer exhibiting tackiness with respect to other members.

In one aspect, from the viewpoints of releasability with respect to an encapsulation resin (for example, an epoxy compound) used in semiconductor encapsulation and the like, and heat resistance that can withstand use in a transfer molding process in which the mold and the encapsulation resin are exposed to high temperatures, it is preferable that the release layer contains a reaction cured product of a hydroxyl group-containing (meth)acrylic polymer and a bifunctional or higher isocyanate compound (hereinafter also referred to as a “polyfunctional isocyanate compound”). In this case, the hydroxyl group-containing (meth)acrylic polymer reacts and crosslinks with a polyfunctional isocyanate compound to form a reaction cured product. The release layer may be a reaction cured product of a hydroxyl group-containing (meth)acrylic polymer, a polyfunctional isocyanate compound, and other components.

A hydroxyl group included in the hydroxyl group-containing (meth)acrylic polymer is a crosslinkable functional group that reacts with an isocyanate group in the polyfunctional isocyanate compound.

A hydroxyl value of the hydroxyl group-containing (meth)acrylic polymer is preferably 1 mgKOH/g or more, more preferably 29 mgKOH/g or more, and is preferably 100 mgKOH/g or less.

When a plurality of types of (meth)acrylic polymers are used in the release layer, the above range is a preferred range for the hydroxyl value of this plurality of types of (meth)acrylic polymers as a whole.

The hydroxyl value is measured by a method specified in JIS K0070:1992.

The hydroxyl group-containing (meth)acrylic polymer may or may not have a carboxy group. The carboxy group, like the hydroxyl group, is a crosslinkable functional group that reacts with the isocyanate group in the polyfunctional isocyanate compound.

An acid value of the hydroxyl group-containing (meth)acrylic polymer is preferably 100 mgKOH/g or less, more preferably 30 mgKOH/g or less, and may be 0 mgKOH/g.

The crosslinkable functional group equivalent of the hydroxyl group-containing (meth)acrylic polymer, that is, the total equivalent of the hydroxyl group and the carboxyl group, is preferably 500 g/mol or more, more preferably 1,000 g/mol or more, and is preferably 2,000 g/mol or less.

The crosslinkable functional group equivalent corresponds to a molecular weight between crosslinking points, and is a physical property value that governs an elastic modulus after crosslinking, that is, an elastic modulus of the reaction cured product. When the crosslinkable functional group equivalent is equal to or more than the above lower limit value, the elastic modulus of the reaction cured product is reduced, and the release layer exhibits excellent extensibility. When the crosslinkable functional group equivalent is equal to or less than the above upper limit value, the elastic modulus of the reaction cured product is increased, and the release layer exhibits excellent releasability with respect to a resin, an electronic component, and the like. Further, migration of the component of the adhesive layer to a resin, an electronic component, or the like is suppressed.

The crosslinkable functional group equivalent of a hydroxyl group-containing (meth)acrylic polymer can be calculated by dividing the molecular weight of potassium hydroxide (56.1) by the sum of the hydroxyl value and acid value of the hydroxyl group-containing (meth)acrylic polymer, followed by multiplication by 1,000.

In the hydroxyl group-containing (meth)acrylic polymer, the hydroxyl group may be present in a side group, may be present at the end of the main chain, or may be present in both the side chain and the main chain. From the viewpoint of ease of adjusting the content of the hydroxyl group, it is preferably present at least in a side group.

The hydroxyl group-containing (meth)acrylic polymer in which a hydroxyl group is present in a side group is preferably a copolymer having the following unit c1 and unit c2.

Unit c1: a hydroxyl group-containing (meth)acrylate unit.

Unit c2: a unit other than the unit c1.

Examples of the unit c1 include a unit represented by the following Formula 1.

—(CH₂—CR¹(COO—R²—OH))— Formula 1

where R¹ is a hydrogen atom or a methyl group, and R² is an alkylene group having 2 to 10 carbon atoms, a cycloalkylene group having 3 to 10 carbon atoms, or —R³—OCO—R⁵—COO—R⁴—, R³ and R⁴ each independently represent an alkylene group having 2 to 10 carbon atoms, and R⁵ is a phenylene group.

R¹ is preferably a hydrogen atom.

The alkylene group represented by R², R³, and R⁴ may be linear or branched.

Specific examples of a monomer to be forming the unit c1 include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid. One type of the monomer to be forming the unit c1 may be used alone or two or more types thereof may be used in combination.

From the viewpoint of excellent reactivity of the hydroxyl group, the unit c1 is preferably one in which R² in the above Formula 1 is an alkylene group having 2 to 10 carbon atoms. In other words, a unit based on a hydroxyalkyl (meth)acrylate having a hydroxyalkyl group of 2 to 10 carbon atoms is preferred.

A ratio of the unit c1 with respect to a total (100 mol %) of all units constituting the hydroxyl group-containing (meth)acrylic polymer is preferably 3 mol % or more, and is preferably 40 mol % or less, more preferably 30 mol % or less, and still more preferably 20 mol % or less. When the ratio of the unit c1 is equal to or more than the above lower limit value, the crosslinking density due to the polyfunctional isocyanate compound is sufficiently high, and the release layer exhibits excellent releasability with respect to a resin, an electronic component, and the like. When the ratio of the unit c1 is equal to or less than the above upper limit value, the release layer exhibits excellent adhesion.

The unit c2 is not particularly limited as long as it can be copolymerized with the monomer forming the unit c1. The unit c2 may have a carboxy group, but preferably does not have a reactive group (for example, an amino group) that can react with an isocyanate group other than the carboxy group.

Examples of a monomer to be forming the unit c2 include a macromer having an unsaturated double bond, a (meth)acrylate without a hydroxyl group, (meth)acrylic acid, and acrylonitrile.

Examples of the macromer having an unsaturated double bond include a macromer having a polyoxyalkylene chain such as a (meth)acrylate of a polyethylene glycol monoalkyl ether.

Examples of the (meth)acrylate without a hydroxyl group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl)trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound in which the alkyl group has 1 to 12 carbon atoms, and examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

The unit c2 preferably includes at least a unit based on an alkyl (meth)acrylate.

A ratio of the alkyl (meth)acrylate unit with respect to a total (100 mol %) of all units constituting the hydroxyl group-containing (meth)acrylic polymer is preferably 60 mol % or more, more preferably 70 mol % or more, and still more preferably 80 mol % or more, and is preferably 97 mol % or less. When the ratio of the alkyl (meth)acrylate unit is equal to or more than the above lower limit value, a glass transition point, mechanical properties and the like derived from the structure of the alkyl (meth)acrylate are exhibited, and the release layer exhibits excellent mechanical strength and tackiness.

When the ratio of the alkyl (meth)acrylate unit is equal to or less than the above upper limit value, the content of the hydroxyl group is sufficient, so that the crosslinking density is increased and a high elastic modulus can be exhibited.

The Mw of the hydroxyl group-containing (meth)acrylic polymer is preferably from 100,000 to 1,200,000, more preferably from 200,000 to 1,000,000, and still more preferably from 200,000 to 700,000. When the Mw is equal to or more than the above lower limit value, the release layer exhibits excellent releasability with respect to a resin, an electronic component, and the like. When the Mw is equal to or less than the above upper limit value, the release layer exhibits excellent adhesion.

The Mw of the hydroxyl group-containing (meth)acrylic polymer is a polystyrene-equivalent value obtained by measurement by gel permeation chromatography using a calibration curve produced using a standard polystyrene sample having a known molecular weight.

A glass transition temperature (Tg) of the hydroxyl group-containing (meth)acrylic polymer is preferably 20° C. or lower, and more preferably 0° C. or lower. When the Tg is equal to or less than the above upper limit value, the release layer exhibits sufficient flexibility even at a low temperature and is unlikely to be delaminated from the base material.

The lower limit value of the Tg is not particularly limited, but within the molecular weight range described above, it is preferably equal to or more than −60° C.

The Tg is a midpoint glass transition temperature measured by differential scanning calorimetry (DSC).

A polyfunctional isocyanate compound is a compound having two or more isocyanate groups in one molecule. The isocyanate group may be protected with a blocking agent.

The number of isocyanate groups in the polyfunctional isocyanate compound is preferably 10 or less, and particularly preferably 3 or less, from the viewpoint of obtaining high extensibility without excessively increasing the crosslinking density of the release layer. The polyfunctional isocyanate compound is most preferably bifunctional or trifunctional.

Examples of the polyfunctional isocyanate compound include hexamethylene diisocyanate (HDI), tolylene diisocyanate (TDI), diphenylmethane diisocyanate (MDI), naphthalene diisocyanate (NDI), tolidine diisocyanate (TODI), isophorone diisocyanate (IPDI), xylene diisocyanate (XDI), triphenylmethane triisocyanate, and tris(isocyanatophenyl)thiophosphate. Further, examples thereof include isocyanurates (that is, trimers) and biurets of these polyfunctional isocyanate compounds, and reaction products of these polyfunctional isocyanate compounds with polyol compounds (for example, adducts, bifunctional prepolymers, trifunctional prepolymers, and the like). Moreover, examples include compounds in which the isocyanate groups of these polyfunctional isocyanate compounds are protected with a blocking agent. Examples of the blocking agent include phenols such as m-cresol and guaiacol, benzenethiol, ethyl acetoacetate, diethyl malonate, and F-caprolactam.

In one aspect, it is preferable that the polyfunctional isocyanate compound has an isocyanurate ring from the viewpoint that the reaction cured product (that is, the adhesive layer) exhibits a high elastic modulus due to flatness of the ring structure.

Examples of the polyfunctional isocyanate compound having an isocyanurate ring include an isocyanurate of HDI (isocyanurate type HDI), an isocyanurate of TDI (isocyanurate type TDI), and an isocyanurate of MDI (isocyanurate type MDI).

A ratio of the isocyanate groups of the polyfunctional isocyanate compound with respect to 100 mol % of the hydroxyl groups of the hydroxyl group-containing (meth)acrylic polymer is preferably from 20 to 115 mol %, more preferably from 25 to 99 mol %, and particularly preferably from 25 to 70 mol %. When the ratio of the isocyanate groups is equal to or less than the above upper limit value, the crosslinking density is sufficiently low, and the adhesion between the release layer and the antistatic layer is excellent. When the ratio of the isocyanate groups is equal to or more than the above lower limit value, the crosslinking density is sufficiently high, and the release layer exhibits excellent releasability with respect to a resin, an electronic component, and the like.

In the release layer, the content of the reaction cured product of the hydroxyl group-containing (meth)acrylic polymer and the polyfunctional isocyanate compound is preferably 50% by mass or more, more preferably 60% by mass or more, and still more preferably 70% by mass or more, with respect to the total mass of the release layer.

The release layer may contain other components other than the above reaction cured product. Examples of the other components include a crosslinking catalyst (for example, amines, a metal compound, an acid, and the like), a reinforcing filler, a coloring dye, a pigment, and an antistatic agent.

The crosslinking catalyst may be any substance that functions as a catalyst for a reaction between the hydroxyl group-containing (meth)acrylic copolymer and the polyfunctional isocyanate compound (that is, a urethanization reaction), and a general urethanization reaction catalyst can be used. Examples of the crosslinking catalyst include an amine compound such as a tertiary amine, and an organometallic compound such as an organotin compound, an organolead compound, and an organozinc compound. Examples of the tertiary amine include a trialkylamine, a N,N,N′,N′-tetraalkyldiamine, a N,N-dialkylamino alcohol, triethylenediamine, a morpholine derivative, and a piperazine derivative. Examples of the organotin compound include a dialkyltin oxide, a dialkyltin fatty acid salt, and a stannous fatty acid salt.

The crosslinking catalyst is preferably an organotin compound, and more preferably dioctyltin oxide, dioctyltin dilaurate, dibutyltin laurate, or dibutyltin dilaurate. In addition, a dialkylacetylacetonetin complex catalyst, which is synthesized by reacting a dialkyltin ester and acetylacetone in a solvent and has a structure in which two molecules of acetylacetone are coordinated to one atom of dialkyltin, can be used.

The amount of the crosslinking catalyst used is preferably from 0.01 to 0.5 parts by mass with respect to 100 parts by mass of the hydroxyl group-containing (meth)acrylic polymer.

The thickness of the release layer is preferably 50 nm or more, and more preferably 100 nm or more, and is preferably 2,000 nm or less, more preferably 1,500 nm or less, and still more preferably 1,000 nm or less. When the thickness of the release layer is equal to or more than the above lower limit value, the releasability is excellent. When the thickness of the release layer is equal to or less than the above upper limit value, the function of the antistatic layer is sufficiently exhibited, and the surface resistance value of the present layered body on the release layer side is low.

The thickness of the release layer is measured by the same method as that described for the average thickness of the antistatic layer. In addition, it can also be measured by the same method as that described for the base material. After coating on the base material, it is also possible to wipe off the release layer during dissolution with a solvent that dissolves it and measure the thickness from the weight difference.

### (Other Layers)

The present layered body may or may not include other layers other than the base material, the antistatic layer, and the release layer. Examples of the other layers include a gas barrier layer and a colored layer. One type of these layers may be used alone or two or more types thereof may be used in combination.

### (Method for Producing Layered Body)

The present layered body is produced, for example, by a method for applying a coating liquid for antistatic layers on one side of a base material to form an antistatic layer.

The surface energy of a surface of the base material to which the coating liquid for antistatic layers is applied, that is, the surface that is contact with the antistatic layer is from 35 to 70 mN/m.

The coating liquid for antistatic layers contains water, a water-miscible organic solvent, and an antistatic agent dispersible in water. The content of water is from 50.0 to 99.9% by mass with respect to the total amount of the coating liquid for antistatic layers. The content of the water-miscible organic solvent is from 14.0 to 30.0% by mass with respect to the total amount of the coating liquid for antistatic layers. The surface tension of the coating liquid for antistatic layers is 34 mN/m or less. By using such a coating liquid for antistatic layers, an antistatic layer with a thickness deviation of less than 30% can be formed. The coating liquid for antistatic layers will be described in detail later.

Before applying the coating liquid for antistatic layers, the surface of the base material onto which the coating liquid for antistatic layers is to be applied may be subjected to a surface treatment.

The base material to be surface-treated (hereinafter also referred to as a “base material to be treated”) may be a commercially available product or may be one produced by a known production method. The base material to be treated can be produced, for example, by forming a molding material containing a resin into a film shape by a known molding method (for example, an extrusion molding method, an inflation molding method or the like). For example, in the extrusion molding method, the molding material is melt-kneaded in an extruder, extruded into a film shape from a die attached to the extruder, and cooled to obtain the base material to be treated. The molding material may contain an additive, and the like.

Examples of the surface treatment include the same as those mentioned above, and a hydrophilization treatment is preferred, and a corona treatment or a plasma treatment is more preferred.

From the viewpoint of industrial productivity, the corona treatment or plasma treatment is preferably carried out continuously from the manufacturing process of the base material to be treated.

The corona treatment and the plasma treatment can each be carried out by a known method.

For example, a voltage is applied between an earthed conveyor roller and an electrode arranged separately to generate a corona discharge, and a long base material to be treated is conveyed by the conveyor roller and passed under the corona discharge, thereby performing a corona treatment on the surface of the base material to be treated on the electrode side.

The distance between the electrode and the conveyor roller is, for example, from 0.1 to 10 mm.

The width of the electrode (in other words, the length of the electrode in the direction perpendicular (in-plane) to the film conveying direction) is preferably, for example, 1 cm or more wider than the film width, and preferably does not exceed the film width by more than 1 m from the viewpoint of efficiency.

The width of the base material to be treated is, for example, from 0.1 to 3 m.

The conveying speed of the base material to be treated is, for example, from 0.1 to 50 m/min.

The electric energy required for the corona treatment is, for example, from 0.1 to 50 kW.

### <Coating Liquid for Antistatic Layers>

When the coating liquid for antistatic layers contains a water-miscible organic solvent, the surface tension of the coating liquid for antistatic layers can be lowered compared to a case where only water is contained as the liquid medium.

The term “water-miscible organic solvent” means an organic solvent compatible with water.

The water-miscible organic solvent may be any organic solvent that is uniformly miscible with water, and examples thereof include alcohols such as methanol, ethanol, isopropyl alcohol (hereinafter also referred to as “IPA”) and butanol; ketones such as acetone; and tetrahydrofuran. One type of the water-miscible organic solvent may be used alone or two or more types thereof may be used in combination. Among these, alcohols are preferred from the viewpoint of excellent compatibility with water, and IPA is particularly preferred.

Examples of the antistatic agent that can be dispersed in water include those mentioned above.

The coating liquid for antistatic layers may contain a binder resin. Examples of the binder resin include those mentioned above, and a carboxy group-containing (meth)acrylic polymer is preferred.

The coating liquid for antistatic layers may contain a curing agent that crosslinks the binder resin. As the curing agent, one that corresponds to the binder resin can be used. When the binder resin is a carboxy group-containing (meth)acrylic polymer, at least one selected from the group consisting of the polyfunctional aziridine compound and polyfunctional epoxy compound described above is preferred. The curing agent may be a carbodiimide.

The coating liquid for antistatic layers may contain other additives.

The content of water is from 50.0 to 99.9% by mass, preferably from 60.0 to 99.9% by mass, more preferably from 70.0 to 95.0% by mass, and still more preferably from 70.0 to 86.0% by mass, with respect to the total amount of the coating liquid for antistatic layers. When the content of water is equal to or more than the above lower limit value, the antistatic agent is favorably dispersed, and the deviation in thickness of the antistatic layer is reduced. When the content of water is equal to or less than the above upper limit value, a sufficient amount of water-miscible organic solvent can be contained.

The content of the water-miscible organic solvent is from 14.0 to 30.0% by mass, preferably from 14.0 to 25.0% by mass, and more preferably from 18.0 to 25.0% by mass, with respect to the total amount of the coating liquid for antistatic layers. When the content of the water-miscible organic solvent is equal to or more than the above lower limit value, the deviation in thickness of the antistatic layer can be reduced. When the content of water is equal to or less than the above upper limit value, the surface tension of the coating liquid for antistatic layers is reduced, the coating liquid for antistatic layers can be uniformly applied onto the base material, and the deviation in thickness of the antistatic layer is reduced. When the content of the water-miscible organic solvent is equal to or less than the above upper limit value, a sufficient amount of water can be contained.

A ratio of water/water-miscible organic solvent is preferably from 999/1 to 1/1, more preferably from 999/1 to 1.5/1, still more preferably from 2.3/1 to 19/1, and particularly preferably from 2.3/1 to 6.1/1. When the above ratio is equal to or more than the above lower limit value, it is advantageous for the dispersion of the antistatic agent, and the storage stability of the coating liquid is excellent. When the above ratio is equal to or less than the above upper limit value, the surface tension of the coating solution is lowered, and unevenness in the coating thickness is reduced.

The solid content concentration of the coating liquid for antistatic layers is preferably from 0.1 to 30.0% by mass, more preferably from 1.0 to 10.0% by mass, and still more preferably from 1.0 to 5.0% by mass, with respect to the total amount of the coating liquid for antistatic layers. When the solid content concentration of the coating liquid for antistatic layers is equal to or more than the above lower limit value, the coatability is excellent. When the solid content of the coating liquid for antistatic layers is equal to or less than the above upper limit value, it is advantageous for the dispersion of the contents, and the storage stability is excellent.

The solid content of the coating liquid for antistatic layers refers to nonvolatile content, and includes the antistatic agent.

The surface tension of the coating liquid for antistatic layers is 34 mN/m or less, preferably 30 mN/m or less, and is preferably 28 mN/m or more. When the surface tension of the coating liquid for antistatic layers is equal to or less than the above upper limit value, the coating liquid for antistatic layers can be uniformly applied onto the base material, and the deviation in thickness of the antistatic layer is reduced. From the viewpoint of coatability, the lower the surface tension of the coating liquid for antistatic layers, the better, but on the other hand, the content of water components in the solution composition increases, which causes problems in the stability of the properties of the coating liquid for antistatic layers. For this reason, although not essential, from the viewpoint of realizing the stability of the properties of the coating liquid, it is preferable that the surface tension is equal to or more than the above lower limit value.

The surface tension of the coating liquid for antistatic layers can be adjusted by the type of the water-miscible organic solvent, the mass ratio between water and the water-miscible organic solvent, and the like.

The surface tension of the coating liquid for antistatic layers is measured at 23° C. using a du Nouy surface tensiometer. Values described in the literature may be used. For example, when the water-miscible organic solvent is IPA, the values described in “Density, refractive index, viscosity, and surface tension of binary systems”, Chemical Engineering, Vol. 22, No. 3, 1958, can be adopted.

The coating liquid for antistatic layers can be prepared by mixing water, a water-miscible organic solvent, an antistatic agent, and, if necessary, a binder resin, a curing agent, and other additives.

### <Formation of Antistatic Layer>

A known coating method can be employed as a method for coating the coating liquid for antistatic layers, and examples thereof include a spin coating method, a spray coating method, an inkjet coating method, a bar coating method, a knife coating method, a roll coating method, a blade coating method, a die coating method, a gravure coating method, a microgravure coating method, a comma coating method, a slot die coating method, a lip coating method, and a solution casting method.

When the coating liquid for antistatic layers is continuously applied onto the base material, a roll coating method, a gravure coating method, a microgravure coating method, a comma coating method, a die coating method, and the like are suitable.

Further, the coating liquid for antistatic layers is mainly composed of water. A coating liquid mainly composed of water generally has low viscosity in many cases, and when applying a coating liquid with such properties, a roll coating method, a gravure coating method, and a microgravure coating method are preferred.

When continuously applying onto the base material using a gravure coating method, a method may be used in which a gravure plate is rotated in the same direction as the base material conveying direction, or a reverse method may be used in which the gravure plate is rotated in the opposite direction. A gravure reverse coating method is most preferred from the viewpoint that the rotational speed can be set independently of the conveying speed of the base material. On the other hand, when forming a thin film of uniform thickness on a sheet of film, a spin coating method is preferred because of its simplicity.

After coating, a coating film of the coating liquid for antistatic layers is dried.

When the material for the base material is a crystalline polymer, the drying temperature is preferably equal to or less than the melting point, and when the material for the base material is an amorphous polymer, the drying temperature is preferably equal to or less than the glass transition temperature. When the base material is a fluororesin film, it is preferable to perform drying at a temperature equal to or less than the melting point of the main material for the base material. Furthermore, the lower the temperature, the smaller the change in shape caused by the release of molding distortion in the base material and the stress applied during the treatment, and a film with high dimensional accuracy can be obtained. In particular, when a fluororesin film is used as the base material, a temperature of 25 to 120° C., or even 40 to 95° C., is preferred.

It is convenient and preferable to perform drying under normal pressure.

After drying, heating may be performed in order to promote curing. The heating temperature at this time is preferably from 40 to 60° C., and the heating time is preferably from 1 to 96 hours.

### <Other Steps>

After forming the antistatic layer, if necessary, a release layer is formed on the surface of the antistatic layer opposite the base material.

The release layer can be formed by a known method. For example, a coating liquid for release layers that contains a component for forming the release layer (for example, the hydroxyl group-containing (meth)acrylic polymer and the polyfunctional isocyanate compound described above) and a liquid medium is applied and dried, thereby forming the release layer. In forming the release layer, heating may be performed in order to promote curing. The heating may be performed each time each layer is formed, or may be performed after forming a plurality of layers.

After forming the antistatic layer, before forming the release layer, or after forming the release layer, any other layer may be formed.

### (Characteristics of Layered Body)

The surface resistance value of the present layered body is not particularly limited, and may be 10¹⁷Ω/□ or less, preferably 10¹²Ω/□ or less, more preferably 10¹¹Ω/□ or less, still more preferably 10¹⁰Ω/□ or less, and particularly preferably 10⁹Ω/□ or less. The lower the surface resistance value, the better, and the lower limit is not particularly limited, but is, for example, 10³Ω/□.

The surface resistance value of the present layered body is measured in accordance with IEC 60093:1980: guarded electrode system with an applied voltage of 500 V and an application time of 1 minute.

When R denotes the surface resistance value (Ω/□) of the present layered body and t denotes the average thickness (nm) of the antistatic layer, the value expressed by 1/(tR) is preferably 0.5×10⁻⁴ or more, more preferably 1.0×10⁻⁴ or more, and still more preferably 2.0×10⁻⁴ or more. 1/(tR) is an index of the conductivity per thickness of the antistatic layer. The larger the value of 1/(tR), the higher the conductivity per thickness of the antistatic layer. When the average thickness of the antistatic layer is the same, the higher the conductivity per thickness of the antistatic layer, the lower the surface resistance value of the layered body. The higher 1/(tR) is, the better, and the upper limit is not particularly limited, but is, for example, 300×10⁻⁴.

### (Use of Layered Body)

The present layered body is useful, for example, as a mold release film used in a step of encapsulating a semiconductor element with a curable resin. Among them, it is particularly useful as a mold release film used in a step of producing a semiconductor package having a complicated shape, for example, an encapsulated body in which a part of an electronic component is exposed from the above resin.

### [Method for Producing Semiconductor Package]

In one aspect, a method for producing a semiconductor package includes:
placing the present layered body on an inner surface of a mold;
placing a substrate to which a semiconductor element is fixed in the aforementioned mold on which the present layered body is placed;
encapsulating the semiconductor element in the aforementioned mold with a curable resin to produce an encapsulated body; and
releasing the aforementioned encapsulated body from the aforementioned mold.

Examples of the semiconductor package include: an integrated circuit in which semiconductor elements such as a transistor and a diode are integrated; and a light-emitting diode including a light-emitting element.

A package shape of the integrated circuit may cover the entire integrated circuit, or may cover a part of the integrated circuit, that is, may expose a part of the integrated circuit. Specific examples thereof include a single in-line package (SIP), a zigzag in-line package (ZIP), a dual in-line package (DIP), a small outline J-leaded package (SOJ), a small outline non-leaded package (SON), a small outline I-leaded package (SOI), a small outline F-leaded package (SOF), a quad flat package (QFP), a quad flat J-leaded package (QFJ), a quad flat non-leaded package (QFN), a quad flat F-leaded package (QFF), a pin grid array (PGA), a land grid array (LGA), a ball grid array (BGA), a dual tape carrier package (DTP), a quad tape carrier package (QTP), a chip size package/chip scale package (CSP), a wafer level CSP (WL-CSP), a leadless lead frame package (LLP), a dual flatpack no-leaded package (DFN), a multi chip package (MCP), a multi chip module (MCM), SiP, a quad in-line package (QIP or QUIP), a ceramic flat package (CFP), a lead less chip carrier (LLCC), a fan out wafer level package (FOWLP), a chip on board (COB), a chip on film (COF), a chip on glass (COG) and a surface vertical package (SVP).

From the viewpoint of productivity, the semiconductor package is preferably produced through collective encapsulation and singulation, and examples thereof include an integrated circuit whose encapsulation method is a molded array packaging (MAP) method or a wafer level packaging (WL) method.

The curable resin is preferably a thermosetting resin such as an epoxy resin and a silicone resin, and more preferably an epoxy resin.

In one aspect, the semiconductor package may or may not include an electronic component such as a source electrode and a seal glass in addition to the semiconductor element. Further, a part of this semiconductor element and the electronic component such as a source electrode and a seal glass may be exposed from the resin.

As a method for producing the above semiconductor package, a known production method can be adopted, with the exception that the present layered body is used. For example, a transfer molding method may be used as a method for encapsulating the semiconductor element, and a known transfer molding device can be used as the device used in this case. The production conditions can also be the same conditions as those in the known method for producing a semiconductor package.

### EXAMPLES

Next, embodiments of the present disclosure will be specifically described with reference to Examples, but the embodiments of the present disclosure are not limited to these Examples. In the following Cases, Cases 1 to 15 and Cases 31 to 33 are Examples, and Cases 21 to 29 are Comparative Examples. The term “part(s)” means “part(s) by mass”.

### (Evaluation Method)

### <Thickness Characteristics>

The thickness of the antistatic layer was measured by optical interferometry at five points evenly spaced in the width direction of the layered body. More specifically, the thickness of the antistatic layer was calculated using a reflection/transmission/film thickness measurement system (F10-RT manufactured by Filmetrics, Inc.) with a refractive index of 1.49. The average value of thicknesses at the five points was taken as the average thickness of the antistatic layer.

Further, the difference between the maximum value and the minimum value of thickness measured at the five points was taken as the “thickness variation at five points,” and the deviation in thickness of the antistatic layer was obtained using the following formula:

$$Deviation in thickness of antistatic layer ( \% ) = thickness variation at five points ( nm ) / average thickness ( nm ) \times 100$$

### <Surface Resistance Value>

At the same five measurement points as those used to measure the thickness characteristics, an ultra-high resistance meter (Resistivity Chamber R12704A manufactured by Advantest Corporation) was used to apply 500 volts in accordance with JIS K 6911:1979, and the surface resistance value (Ω/□) of the layered body on the opposite side to the base material side was measured after one minute. The average value of surface resistance values at the five points was taken as the surface resistance value of the layered body.

The surface resistance value (Ω/□) of the layered body was denoted as R, the average thickness (nm) of the antistatic layer was denoted as t, and the value of 1/(tR) was calculated. The larger the value of 1/(tR), the better the conductivity per thickness of the antistatic layer.

### <Appearance>

Since the film used as the base material has a lower refractive index than that of the antistatic layer, color unevenness occurs when there is thickness unevenness. Accordingly, the produced layered body was pulled out by 1 m, visually observed indoors under a fluorescent lamp, and evaluated according to the following criteria. It should be noted that if a coating film of the coating liquid for antistatic layers could not be formed when forming the antistatic layer, visual evaluation was not performed and the result was evaluated as D.
A: A uniform color is observed, and thickness unevenness cannot be recognized visually.
B: Although there are local differences in brightness such as streaks, the color is almost constant overall, and thickness unevenness cannot be recognized.
C: There are parts that show various colors in the overall layered body, and thickness unevenness can be recognized visually.
D: No coating film can be formed.

### (Materials Used)

### <Materials for Base Material>

ETFE-1: a copolymer of TFE/ethylene/PFBE=56.3/40.2/3.5 (molar ratio) produced in the same manner as in Production Example 2 (paragraph 0118) of International Patent Publication No. 2015/133630.

### <Materials for Antistatic Layer>

Main agent 1: Aracoat (registered trademark) AD610 (manufactured by Arakawa Chemical Industries, Ltd.). An aqueous composition containing poly(3,4-ethylenedioxythiophene)-polystyrene sulfonate (PEDOT-PSS), carboxy group-containing (meth)acrylic polymer, water and IPA. Solid content concentration: 4.9% by mass, water: 89.3% by mass, IPA: 5.8% by mass.

Main agent 2: PP6806 (manufactured by KJ Specialty Paper Co., Ltd.). An aqueous CNT antistatic coating material. Solid content concentration: 10% by mass, water: 90% by mass.

Curing agent 1: Aracoat CL910 (manufactured by Arakawa Chemical Industries, Ltd.). An IPA solution of trifunctional aziridine compound (2,2-bishydroxymethylbutanol-tris[3-(1-aziridinyl)propionate], aziridine equivalent: 142 g/eq). Solid content concentration: 9.5% by mass, IPA: 90.5% by mass.

Curing agent 2: V-02 (manufactured by Nisshinbo Chemical Inc.). Carbodilite: a crosslinking agent for a waterborne resin. An aqueous solution of trifunctional aziridine compound (2,2-bishydroxymethylbutanol-tris[3-(1-aziridinyl)propionate], NCN equivalent: 590 g/eq). Solid content concentration: 40% by mass, water: 60% by mass.

### <Materials for Release Layer>

Main agent 3: Nissetsu (registered trademark) KP2562 (manufactured by Nippon Carbide Industries Co., Inc.). Diluted solution of hydroxyl group-containing (meth)acrylic polymer (hydroxyl value: 70 mg KOH/g, crosslinkable functional group equivalent: 801 g/mol) 801 g/mol), solid content: 35% by mass.

Curing agent 3: Nissetsu CK-157 (manufactured by Nippon Carbide Industries Co., Inc.), solid content: 100% by mass, isocyanurate type hexamethylene diisocyanate, NCO content: 21% by mass.

### (Case 1)

### <Production of Base Material>

ETFE-1 was molded into a film with a width of 1,500 mm and a thickness of 100 μm at a temperature of 300° C. by a T-die method using an extruder (90 mmp, L/D=24). One side of the film was a mirror surface (Ra=0.05 μm), and the other side was a matte surface (Ra=2.2 μm). At the same time as molding, a corona treatment as a hydrophilization treatment was conducted over the entire width of the mirror surface side. In the corona treatment, an electrode with an electrode width of 2.65 m and an earthed conveyor roller were arranged so as to have a gap of about 5 mm, and five electrodes were arranged by parallel connection to adjust the current to flow evenly. The corona treatment was performed with an electric energy of 1,800 W while allowing the molded film to pass through this gap at 13 m/min. After the corona treatment, the surface energy of the mirror surface (corona-treated surface) side of the film was evaluated by a surface energy evaluation method using a wetting indicator based on ISO 8296:2003, and was found to be 52 mN/m.

### <Preparation of Coating Liquid for Antistatic Layers>

10 parts of the main agent 1, 1 part of the curing agent 1, and 1.5 parts of water and 1.5 parts of IPA as dilution media were mixed and stirred for 5 minutes to obtain a coating liquid for antistatic layers.

### <Production of Layered Body>

The produced base material was placed in a film coater with a roll coater section of a direct gravure reverse method, and the coating liquid for antistatic layers was applied onto the mirror surface side, and dried at 65° C. for 1 minute to form an antistatic layer. A gravure plate with 150 lines and a depth of 45 μm was used, and the peripheral speed ratio during coating was 130%.

The obtained layered body was evaluated as described above, and the average thickness of the antistatic layer was 238 nm, the thickness variation at 5 points was 21 nm, and the deviation was 9%. The appearance of the layered body was evaluated as A, the surface resistance value was 20.0×10⁷, and 1/(tR) was 2.1×10⁻⁴.

### (Cases 2 to 8, 21 to 23)

Layered bodies were obtained in the same manner as in Case 1, with the exception that the amounts of each material added were changed as shown in Tables 1 to 2 in the preparation of the coating liquid for antistatic layers. The evaluation results of the obtained layered bodies are shown in Tables 1 and 2.

### (Case 9)

A layered body was obtained in the same manner as in Case 1, with the exception that in the production of the layered body, the base material was attached to a 3-inch silicon wafer so as not to introduce wrinkles, the coating liquid for antistatic layers was applied onto the base material by a spin coating method under conditions of 2,000 rpm for 1 minute, and dried at 65° C. for 5 minutes in a circulating oven to form an antistatic layer. The evaluation results of the obtained layered body are shown in Table 1.

### (Case 10)

A layered body was obtained in the same manner as in Case 1, with the exception that a plasma treatment was performed instead of a corona treatment in the production of the base material. The plasma treatment was performed by applying a high-frequency voltage of 110 KHz in an argon atmosphere at an atmospheric pressure of 0.2 Torr, with a discharge power density of 300 Wmin/m². After the plasma treatment, the surface energy of the mirror surface (corona-treated surface) side of the film was evaluated in the same manner as in Case 1, and was found to be 58 mN/m. The evaluation results of the obtained layered body are shown in Table 1.

### (Cases 11 and 27)

Layered bodies were obtained in the same manner as in Case 1 or Case 11, with the exception that the electric energy in the corona treatment was 1,800 W. The evaluation results of the obtained layered bodies are shown in Tables 1 and 2.

### (Cases 12 and 28)

Layered bodies were obtained in the same manner as in Case 1 or Case 11, with the exception that in the corona treatment, the speed at which the film was allowed to pass through the gap was 7.2 m/min and the electric energy was 8,500 W. The evaluation results of the obtained layered bodies are shown in Tables 1 and 2.

### (Cases 13 and 29)

Layered bodies were obtained in the same manner as in Case 1 or Case 11, with the exception that in the corona treatment, the speed at which the film was allowed to pass through the gap was 9 m/min and the electric energy was 2,250 W. The evaluation results of the obtained layered bodies are shown in Tables 1 and 2.

### (Case 14)

A layered body was obtained in the same manner as in Case 13, with the exception that in the preparation of the coating liquid for antistatic layers, the curing agent 2 was used as a curing agent, and 2 parts of IPA were used instead of 1.5 parts of water and 1.5 parts of IPA as dilution solvents. The evaluation results of the obtained layered body are shown in Table 1.

### (Case 15)

A layered body was obtained in the same manner as in Case 13, with the exception that in the preparation of the coating liquid for antistatic layers, the main agent 2 was used as a main agent, and 3 parts of IPA were used instead of 1.5 parts of water and 1.5 parts of IPA as dilution solvents. The evaluation results of the obtained layered body are shown in Table 1.

### (Case 24)

A layered body was obtained in the same manner as in Case 1, with the exception that in the preparation of the coating liquid for antistatic layers, the main agent 2 was used as a main agent, and 10 parts of methanol was used instead of 1.5 parts of water and 1.5 parts of IPA as dilution media. The evaluation results of the obtained layered body are shown in Table 2.

### (Case 25)

A layered body was obtained in the same manner as in Case 1, with the exception that in the preparation of the coating liquid for antistatic layers, after adding 500 parts of IPA instead of 1.5 parts of water and 1.5 parts of IPA as dilution media, the resulting mixture was concentrated using an evaporator until the weight was 60% of the initial weight, and a coating liquid with a final mixed solvent composition of IPA/toluene/water=50/40/10 (mass ratio) prepared by further adding toluene was used. The evaluation results of the obtained layered body are shown in Table 2.

### (Case 26)

When an attempt was made to obtain a layered body in the same manner as in Case 1, with the exception that no corona treatment was performed in the preparation of the base material, the coating liquid for antistatic layers was repelled when it was applied, and no coating film could be formed.

In Tables 1 and 2, “10\hat{ }7 ” indicates 10 to the power of 7, and “10\hat{ }(−4)” indicates 10 to the power of −4.

For the surface tension of the coating liquid for antistatic layers, in the case of an example in which the water-miscible organic solvent was IPA, the surface tension of a mixed solution of water and IPA was obtained, in accordance with the mass ratio of water and IPA, from the description in the literature (“Density, refractive index, viscosity, and surface tension of binary systems”, Chemical Engineering, Vol. 22, No. 3, 1958), and this value was used as the surface tension of the coating liquid for antistatic layers. In Case 15, the surface tension value of toluene alone was used as the surface tension of the coating liquid for antistatic layers.

TABLE 1

| Case | | | 1 | 2 | 3 | 4 | 5 | 6 | 7 | 8 |
|---|---|---|---|---|---|---|---|---|---|---|
| Base material | Material | | ETFE | ETFE | ETFE | ETFE | ETFE | ETFE | ETFE | ETFE |
| | Thickness (μm) | | 100 | 100 | 100 | 100 | 100 | 100 | 100 | 100 |
| | Surface treatment | | Corona | Corona | Corona | Corona | Corona | Corona | Corona | Corona |
| | Surface energy (mN/m) | | 52 | 52 | 52 | 52 | 52 | 52 | 52 | 52 |
| Coating liquid | Main agent 1 (parts) | | 10 | 10 | 10 | 10 | 10 | 10 | 10 | 10 |
| for antistatic | Main agent 2 (parts) | | 0 | 0 | 0 | 0 | 0 | 0 | 0 | 0 |
| layers | Curing agent 1 (parts) | | 1 | 1 | 1 | 1 | 0.5 | 0.5 | 0.3 | 0.3 |
| | Curing agent 2 (parts) | | 0 | 0 | 0 | 0 | 0 | 0 | 0 | 0 |
| | Dilution | Water (parts) | 1.5 | 0.2 | 0 | 4 | 0 | 0 | 0 | 1.5 |
| | medium | IPA (parts) | 1.5 | 0.2 | 0.2 | 4 | 1 | 0.5 | 0.7 | 1.5 |

| | | | | | | | | | |
|---|---|---|---|---|---|---|---|---|---|
| | Solid content concentration | 4.2% | 5.1% | 5.2% | 3.1% | 4.9% | 4.9% | 4.7% | 3.9% |
| | Water | 74.5% | 80.1% | 79.8% | 65.0% | 77.4% | 81.1% | 81.2% | 78.4% |
| | Water-miscible organic solvent | 21.3% | 14.8% | 15.0% | 28.9% | 17.7% | 14.0% | 14.1% | 17.7% |
| | Surface tension (mN [symbol] m) | 29 | 34 | 34 | 38 | 31 | 34 | 34 | 29 |
| Ancistatic layer | Average thickness (nm) | 258 | 289 | 294 | 173 | 245 | 278 | 282 | 221 |
| | Thickness variation at 5 points (nm) | 21 | 64 | 71 | 31 | 24 | 58 | 64 | 24 |
| | Deviation in thickness (%) | 9 | 22 | 24 | 6 | 10 | 21 | 23 | 11 |

| | | | | | | | | |
|---|---|---|---|---|---|---|---|---|
| Appearance evaluation | A | B | B | A | A | B | B | A |
| Surface resistance value ×10 [symbol] (Ω/ [symbol] ) | 20.0 | 17.3 | 17.5 | 26.7 | 19.9 | 17.3 | 17.0 | 21.8 |
| [symbol] /( [symbol] ) ×10\hat{ }( [symbol] ) | 2.1 | 2.0 | 1.9 | 2.1 | 2.1 | 2.1 | 2.1 | 2.1 |

| Case | | 9 | 10 | 11 | 12 | 13 | 14 | 15 |
|---|---|---|---|---|---|---|---|---|
| Base material | Material | ETFE | ETFE | ETFE | ETFE | ETFE | ETFE | ETFE |
| | Thickness (μm) | 100 | 100 | 100 | 100 | 100 | 100 | 100 |
| | Surface treatment | Corona | Plasma | Corona | Corona | Corona | Corons | Corona |
| | Surface energy (mN/m) | 52 | 58 | 44 | 47 | 58 | 58 | 58 |
| Coating liquid | Main agent 1 (pants) | 10 | 10 | 10 | 10 | 10 | 10 | 0 |
| for antistatic | Main agent 2 (parts) | 0 | 0 | 0 | 0 | 0 | 0 | 10 |
| layers | Curing agent 1 (parts) | 1 | 1 | 1 | 1 | 1 | 0 | 1 |
| | Curing agent 2 (parts) | 0 | 0 | 0 | 0 | 0 | 1 | 0 |

| | | | | | | | | |
|---|---|---|---|---|---|---|---|---|
| Dilution | Water (parts) | 1.5 | 1.5 | 1.5 | 1.5 | 1.5 | 0 | 0 |
| medium | IPA (parts) | 1.5 | 1.5 | 1.5 | 1.5 | 1.5 | 2 | 3 |

| | | | | | | | | |
|---|---|---|---|---|---|---|---|---|
| | Solid content concentration | 4.2% | 4.2% | 4.2% | 4.2% | 4.2% | 6.8% | 7.7% |
| | Water | 74.5% | 74.5% | 74.5% | 74.5% | 74.5% | 71.9% | 67.3% |
| | Water-miscible organic solvent | 21.3% | 21.3% | 21.3% | 21.3% | 21.3% | 21.3% | 25.0% |
| | Surface tension (mN [symbol] m) | 29 | 29 | 29 | 29 | 29 | 29 | 28 |
| Ancistatic layer | Average thickness (nm) | 273 | 280 | 210 | 263 | 248 | 310 | 330 |
| | Thickness variation at 5 points (nm) | 3 | 25 | 35 | 28 | 19 | 32 | 58 |
| | Deviation in thickness (%) | 1 | 9 | 17 | 11 | 3 | 10 | 13 |

| | | | | | | | |
|---|---|---|---|---|---|---|---|
| Appearance evaluation | A | A | A | A | A | A | A |
| Surface resistance value ×10 [symbol] (Ω/ [symbol] ) | 16.7 | 17.4 | 22.6 | 18.2 | 19.4 | 15.8 | 14.0 |
| [symbol] /( [symbol] ) ×10\hat{ }( [symbol] ) | 2.2 | 2.1 | 2.1 | 2.1 | 2.1 | 2.0 | 2.2 |

[symbol]

indicates data missing or illegible when filed

TABLE 2

| Case | | | 21 | 22 | 23 | 24 | 25 | 26 | 27 | 28 | 29 |
|---|---|---|---|---|---|---|---|---|---|---|---|
| Base material | Material | | ETFE | ETFE | ETFE | ETFE | ETFE | ETFE | ETFE | ETFE | ETFE |
| | Thickness (μm) | | 100 | 100 | 100 | 100 | 100 | 100 | 100 | 100 | 100 |
| | Surface treatment | | Corona | Corona | Corona | Corona | Corona | Corona | Corona | Corona | Corona |
| | Surface energy (mN/m) | | 52 | 52 | 52 | 52 | 52 | <22.6 | 44 | 47 | 58 |
| Coating liquid | Main agent 1 (parts) | | 10 | 10 | 10 | 10 | 10 | 10 | 10 | 10 | 10 |
| for antistatic | Main agent 2 (parts) | | 0 | 0 | 0 | 0 | 0 | 0 | 0 | 0 | 0 |
| layers | Curing agent 1 (parts) | | 1 | 1 | 1 | 1 | 1 | 1 | 1 | 1 | 1 |
| | Curing agent 2 (parts) | | 0 | 0 | 0 | 0 | 0 | 0 | 0 | 0 | 0 |
| | Dilution | Water (parts) | 0 | 5 | 10 | 0 | Diluted with | 1.5 | 0 | 0 | 0 |
| | medium | IPA (parts) | 0 | 5 | 10 | Meth- | IPA/toluene/ | 1.5 | 0 | 0 | 0 |
| | | | | | | anol | water = 50/40/10 | | | | |
| | | | | | | 10 | (solvent | | | | |
| | | | | | | | substitution) | | | | |

| | | | | | | | | | | |
|---|---|---|---|---|---|---|---|---|---|---|
| | Solid content concentration | 5.3% | 2.8% | 1.9% | 2.8% | 5% | 4.2% | 5.3% | 5.3% | 5.3% |
| | Water | 81.2% | 66.3% | 61.1% | 42.1% | 10% | 74.5% | 81.2% | 81.2% | 81.2% |
| | Water-miscible organic solvent | 13.5% | 30.9% | 37.0% | 55.1% | 50% | 21.3% | 13.5% | 13.5% | 13.5% |
| | Surface tension (mN/m) | 35 | 27 | 27 | 25 | 28.5 or less | 29 | 35 | 35 | 35 |
| | | | | | | (toluene alone) | | | | |
| Antistatic layer | Average thickness (nm) | 300 | 158 | 108 | 113 | 148 | No coating | 263 | 239 | 320 |
| | Thickness variation at 5 points | 294 | 168 | 75 | 150 | 232 | film could | 274 | 263 | 350 |
| | (nm) | | | | | | be formed | | | |
| | Deviation in thickness (%) | 98 | 106 | 70 | 133 | 157 | | 104 | 110 | 109 |

| | | | | | | | | | |
|---|---|---|---|---|---|---|---|---|---|
| Appearance evaluation | C | C | C | C | C | D | C | C | C |
| Surface resistance value ×10\hat{ }7 (Ω/ [symbol] ) | 148 | 305 | 324 | 597 | 15,000 | >10\hat{ }7 | 176 | 225 | 163 |
| [symbol] /( [symbol] ) ×10\hat{ }( [symbol] ) | 0.2 | 0.2 | 0.3 | 0.1 | 0.005 | — | 0.2 | 0.2 | 0.2 |

[symbol]

indicates data missing or illegible when filed

As shown in Tables 1 and 2, the layered bodies of Cases 1 to 15 had surface resistance values of 26.7×10⁷ or less, and were excellent in antistatic performance. Since 1/(tR) was 1.9×10⁻⁴ or more, it can be seen that the conductivity per thickness of the antistatic layer was excellent. In addition, the layered bodies of Cases 1 to 15 also had favorable appearances.

On the other hand, the layered bodies of Cases 21 to 29 had surface resistance values of 148×10⁷ or more, and were inferior in antistatic performance. Since 1/(tR) was 0.3×10⁻⁴ or less in all of Cases 21 to 25 and 27 to 29 in which an antistatic layer was formed, it can be seen that the conductivity per thickness of the antistatic layer was inferior. In addition, the layered bodies of Cases 21 to 25 and 27 to 29 also had poor appearances.

### (Cases 31 to 33)

The main agent 3, the curing agent 3, and ethyl acetate were mixed in the amounts shown in Table 3 to prepare a coating liquid for release layers. The amount of ethyl acetate added in Cases 31 and 32 was set to an amount such that the solid content of the coating liquid for release layers was 16% by mass. The amount of ethyl acetate added in Case 33 was set to an amount such that the solid content of the coating liquid for release layers was 15% by mass. The coating liquid for release layers was applied onto the surface of the antistatic layer side of the layered body obtained in each of Cases 1, 8, and 6 using a gravure coater, and dried to form a release layer with a thickness of 0.8 μm. The coating was performed by a direct gravure method using a 100 mm (diameter)×250 mm (width) roller with a grid 150 (mesh)−40 μm (depth) as a gravure plate. The drying was performed at 100° C. for 1 minute through a roll support drying oven with an air volume of 19 m/sec. Subsequently, curing was performed under conditions of 40° C. for 120 hours to obtain a layered body in which the base material, antistatic layer, and release layer were laminated in this order.

The appearance of the obtained layered body was evaluated. The results are shown in Table 3.

TABLE 3

| Case | | 31 | 32 | 33 |
|---|---|---|---|---|
| Layered body | | Case 1 | Case 8 | Case 6 |
| Coating liquid for | Main agent 3 (parts) | 100 | 100 | 100 |
| release layers | Curing agent 3 (parts) | 6 | 6 | 3 |
| | Ethyl acetate (parts) | 150 | 150 | 150 |

| | | | |
|---|---|---|---|
| Solid content concentration | 16% | 16% | 15% |
| Appearance evaluation | A | A | A |

As shown in Table 3, in Cases 31 to 33, even after forming the release layer on the antistatic layer, the excellent appearance was maintained as before the formation of the release layer.

### INDUSTRIAL APPLICABILITY

The film of the present disclosure is a layered body with excellent antistatic performance. By using the film of the present disclosure as a mold release film, a semiconductor package such as an integrated circuit in which semiconductor elements such as a transistor and a diode and electronic components such as a source electrode and sealing glass are integrated can be produced.

### REFERENCE SIGNS LIST

1 Layered body
2 Base material
3 Antistatic layer
4 Release layer

1: A layered body, comprising:
a film-like base material and an antistatic layer provided on one side of said base material,
wherein a surface of said base material that is contact with said antistatic layer has a surface energy of 35 to 70 mN/m, and a thickness deviation of said antistatic layer is less than 30%.

2: The layered body according to claim 1, wherein said antistatic layer comprises a water-dispersible antistatic agent.

3: The layered body according to claim 2, wherein said antistatic agent comprises at least one selected from the group consisting of a conductive polymer and a conductive filler.

4: The layered body according to claim 1, wherein said base material comprises at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

5: The layered body according to claim 4, wherein said fluororesin comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

6: The layered body according to claim 1, wherein a surface of said base material that is contact with said antistatic layer is subjected to a corona treatment or plasma treatment.

7: The layered body according to claim 1, further comprising:
a release layer positioned on a surface of said antistatic layer on an opposite side with respect to said base material.

8: A mold release film for encapsulating a semiconductor element with a curable resin, comprising:
the layered body of claim 1.

9: A production method of a layered body, comprising:
applying a coating liquid for antistatic layers onto one surface of a film-like base material to form an antistatic layer,
wherein a surface of said base material onto which said coating liquid for antistatic layers is applied has a surface energy of 35 to 70 mN/m, said coating liquid for antistatic layers comprises water, a water-miscible organic solvent, and a water-dispersible antistatic agent, a content of said water is from 50.0 to 99.9% by mass with respect to a total amount of said coating liquid for antistatic layers, a content of said water-miscible organic solvent is from 14.0 to 30.0% by mass with respect to the total amount of said coating liquid for antistatic layers, and a surface tension of said coating liquid for antistatic layers is 34 mN/m or less.

10: The production method according to claim 9, wherein said water-miscible organic solvent comprises an alcohol.

11: The production method according to claim 10, wherein said alcohol comprises isopropyl alcohol.

12: The production method according to claim 1, wherein a surface of said base material onto which said coating liquid for antistatic layers is to be applied is subjected to a corona treatment or a plasma treatment before applying said coating liquid for antistatic layers.

13: The production method according to claim 9, further comprising:
forming a release layer on a surface of said antistatic layer opposite said base material after forming said antistatic layer.

14: A method for producing a semiconductor package, comprising:
placing the layered body of claim 1 on an inner surface of a mold;
placing a substrate to which a semiconductor element is fixed in said mold on which said layered body is placed;
encapsulating the semiconductor element in said mold with a curable resin to produce an encapsulated body; and
releasing said encapsulated body from said mold.

15: The layered body according to claim 2, wherein said base material comprises at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

16: The layered body according to claim 15, wherein said fluororesin comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.

17: The layered body according to claim 2, wherein a surface of said base material that is contact with said antistatic layer is subjected to a corona treatment or plasma treatment.

18: The layered body according to claim 2, further comprising:
a release layer positioned on a surface of said antistatic layer on an opposite side with respect to said base material.

19: The layered body according to claim 3, wherein said base material comprises at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

20: The layered body according to claim 19, wherein said fluororesin comprises at least one selected from the group consisting of an ethylene-tetrafluoroethylene copolymer, a tetrafluoroethylene-hexafluoropropylene copolymer, a tetrafluoroethylene-perfluoro(alkyl vinyl ether) copolymer, and a tetrafluoroethylene-hexafluoropropylene-vinylidene fluoride copolymer.
